(19) United States
(12) Patent Application Publication
(10) Pub. No.: US 2010/0304554 A1
(43) Pub. Date: Dec. 2, 2010

(54) PRODUCTION METHOD FOR SEMICONDUCTOR DEVICE

(76) Inventors: Yoshiharu Hidaka, Osaka (JP); Kou Sugano, Osaka (JP)

Correspondence Address: MCDERMOTT WILL & EMERY LLP, 600 13TH STREET, NW, WASHINGTON, DC, 20005-3096, US

(21) Appl. No.: 12/526,217

(22) PCT Filed: Jan. 6, 2009
(86) PCT No.: PCT/JP2009/000009

§ 371 Date: Aug. 6, 2009

(30) Foreign Application Priority Data
Jan. 11, 2008 (JP) 2008-005026

(51) Int. Cl. H01L 21/265; H01L 21/306

(52) U.S. Cl. 438/514; 257/E21.334; 257/E21.224

(57) ABSTRACT

In a production method for a semiconductor device relating to the present invention, first, a pattern of a resist film made of organic polymers is formed on a semiconductor substrate. Next, impurity ions with 1×10¹⁴ cm⁻² or greater of dose amount are implanted into the semiconductor substrate using the resist film pattern as a mask. The resist film pattern mask is removed sequentially through an oxidation treatment, swelling treatment and removal treatment. In the oxidation treatment, a treatment to oxidize a hardened layer formed in a surface portion of the resist film pattern by the ion implantation is implemented. In the swelling treatment, a treatment to swell the organic polymers composing the resist film pattern where the hardened layer has been oxidized using a chemical solution is implemented. In the removal treatment, the swollen resist film pattern is removed using the chemical solution used for the swelling treatment.

### TECHNICAL FIELD

The present invention relates to a production method for a semiconductor device, and relates to a production method for a semiconductor device including a process of removing a resist film whose surface is hardened due to ion bombardment without affecting a base layer of the resist film.

### BACKGROUND ART

In a production process of a semiconductor device, such as a semiconductor integrated circuit device, a treatment where a pattern of photosensitive resin film, such as a photo resist film, is formed on a semiconductor substrate and the pattern is used as a mask is often used. For example, in ion implantation process, impurities are introduced into the semiconductor substrate using the pattern as a mask. For example, a source region, a drain region and an extension region of a MOS (metal oxide semiconductor) transistor are formed with this process.

In a formation process of a semiconductor device equipped with a P-channel transistor and an N-channel transistor on a same semiconductor substrate, for example, ions are implanted into an N-channel transistor formation region while a resist pattern for covering a P-channel transistor formation region is formed. When the ion implantation has been completed, the resist pattern is removed. Then, while a resist pattern for covering the N-channel transistor formation region is formed, ions are implanted into the P-channel transistor formation region. For removing the resist pattern, a sulfuric acid-hydrogen peroxide mixture at approximately 130 deg. C. (hereafter, referred to as heated SPM) is widely used.

However, recently, in order to reduce an occupied area for the MOS transistor; and concurrently, to improve its drive capability, there is a demand to form the impurity region at an extremely shallow depth with a high concentration. The ion species to be used for forming an impurity region are boron (B) or arsenic (As), and in order to form a shallow impurity region, nitrogen (N₂) may be implanted into a semiconductor substrate before implanting the ions.

When a dose amount of impurities to be ion-implanted exceeds 1×10¹⁴ cm⁻², the resist pattern receives an ion bombardment, and the surface of the resist pattern becomes hardened. If the resist pattern where a hardened layer is formed in a surface portion is attempted to be removed using the heated SPM, a treatment time becomes extremely longer, and taking a throughput in the production process into consideration, it becomes realistically difficult to remove the resist pattern only with the heated SPM. Consequently, when the resist pattern where the hardened layer is formed is removed, first, ashing treatment of the resist pattern using oxygen plasma is implemented.

FIG. 9 is a flowchart showing a conventional process flow from the ion implantation to the resist pattern removal. As shown in FIG. 9, first, a resist pattern to be an ion implantation mask is formed on a semiconductor substrate (step S101). Next, a predetermined ion species is ion-implanted into the semiconductor substrate using the formed resist pattern as a mask (step S102). This ion implantation includes ion implantation for forming a well layer in the semiconductor substrate, ion implantation for forming an extension region of a MOS transistor, ion implantation for forming a pocket region adjacent to a source region or a drain region, and ion implantation for forming a source region and a drain region. A hardened layer is formed in a surface portion of the resist pattern depending upon implantation conditions (implantation dose amount, implantation energy) of the ion implantation.

When the ion implantation is complete, the resist pattern is removed. In removing the resist pattern, first, the hardened layer is removed via an ashing treatment using oxygen plasma (hereafter, referred to as an O₂ ashing treatment) (step S103). Next, resist residues remaining on the surface of the semiconductor substrate are removed via a cleaning treatment using the heated SPM (step S104). Since the resist residue is a resin constituting a resist pattern bottom where hardening hardly progresses, it is removable using the heated SPM. In addition, in the cleaning treatment using the heated SPM, since particles on the surface of the semiconductor substrate often remain, the residual particles on the semiconductor substrate are removed via a cleaning treatment using ammonium hydroxide-hydrogen peroxide mixture (hereafter, referred to as APM) (step S105).

In the meantime, in Japanese Patent Application Laid-Open No. 2004-327537 (Patent Citation 1) and Japanese Patent Application Laid-Open No. 2006-93473 (Patent Citation 2), a technique to remove a resist pattern without using the O₂ ashing treatment is proposed. For example, in the technology disclosed in Patent Citation 1, first, a treatment only with water vapor at high temperature, which is higher than the highest heat treatment temperature on the occasion of forming the resist pattern, causes the generation of a local rupture of the resist, referred to as popping, in a surface portion of the resist pattern. Then, the resist pattern is removed by treating in an atmosphere where ozone and water vapor are mixed. Further, in Patent Citation 1, a treatment with SPM after the treatment with the mixed gas of ozone and water vapor is described. In the meantime, in Patent Citation 2, it is disclosed that after water vapor at 95 deg. C. or higher is filled in a sealed chamber, spraying ozone gas enables the resist removal even in the case that a dose amount of ion implantation exceeds 1×10¹⁴ cm⁻², as well.

Patent Citation 1: Japanese Patent Application Laid-Open No. 2004-327537

Patent Citation 2: Japanese Patent Application Laid-Open No. 2006-93473

### DISCLOSURE OF INVENTION

### Technical Problem

However, if the O₂ ashing treatment is used for the removal of the resist pattern, the surface of the semiconductor substrate is also oxidized by oxygen plasma. Such oxidation of the surface portion of the semiconductor substrate causes problems mentioned below in a production process of a semiconductor device using a process technology with 65 nm, 45 nm or less.

FIGS. 10A and 10B are cross sectional views for explaining an influence of the O₂ ashing treatment on an N-channel transistor and a P-channel transistor formed in a CMOS (complementary metal oxide semiconductor) process. In FIGS. 10A and 10B, the N-channel transistor is shown on the left; concurrently, the P-channel transistor is shown on the right. Further, FIGS. 10A and 10B show processes to form high concentration impurity regions functioning as a source region and a drain region of the N-channel transistor in the semiconductor substrate where a source region and a drain region of the P-channel transistor have already been formed.

As shown in FIG. 10A, the P-channel transistor and the N-channel transistor are formed on the surface of a silicon single crystal substrate 100 separated by trench element isolation regions (STI: shallow trench isolation) 101. The P-channel transistor is equipped with a gate electrode 114 made of poly-crystalline silicon formed on an N-type well layer 112 via a gate insulating film 113. The gate electrode 114 is equipped with sidewalls composed of an L-shaped silicon oxide film 115 and silicon nitride film 116 on both sides.

Further, the N-channel transistor is equipped with a gate electrode 104 made of poly-crystalline silicon formed on a P-type well layer 102 via a gate insulating film 103. The gate electrode 104 is equipped with sidewalls composed of an L-shaped silicon oxide film 105 and silicon nitride film 106 on both sides.

In addition, extension regions 117 and high concentration impurity regions 118 that function as the source region and the drain region are formed by ion implantation in the surface portion of the silicon single crystal substrate 100 at both sides of the gate electrode 114 of the P-channel transistor in a formation region of the P-channel transistor. Further, extension regions 107 are formed by ion implantation in the surface portion of the silicon single crystal substrate 100 at both sides of the gate electrode 104 in a formation region of the N-channel transistor.

In the case of forming the high concentration impurity regions of the N-channel transistor, a resist pattern 121 for covering the formation region of the P-channel transistor is formed on the silicon single crystal substrate 100. Under this condition, N-type impurity ions with approximately 1×10¹⁵ cm⁻² of dose amount are implanted and N-type high concentration impurity regions 108 are formed in the surface portion of the silicon single crystal substrate 100 at both sides of the gate electrodes 104.

When the ion implantation is completed, the resist pattern 121 is removed. In this case, since an alteration layer is formed in a surface portion of the resist pattern 121, the O₂ ashing treatment is implemented to the removal of the resist pattern 121. While the O₂ ashing treatment is implemented, the high concentration impurity regions 108 of the N-channel transistor formation region and the gate electrode 104 are exposed to the oxygen plasma. Consequently, silicon oxide films 109 and 110 having a thickness within a range of 4 nm to 6 nm are formed on the surfaces of the high concentration impurity regions 108 and the gate electrode 104 as shown in FIG. 10B, respectively. Furthermore, the film thickness of the silicon oxide film to be formed in the case of removing the resist pattern not having any alteration layer using the heated SPM is approximately 1.5 nm. Therefore, the film thickness of the silicon oxide film to be formed by the O₂ ashing treatment is notably greater than that by the treatment using the heated SPM.

Further, when the resist pattern 121 is removed in the process of the O₂ ashing treatment, the gate electrode 114 and the high concentration impurity regions 118 of the P-channel transistor are exposed to the oxygen plasma. Therefore, silicon oxide films 119 and 120 are also formed on the surfaces of the high concentration impurity regions 118 and the gate electrode 114, respectively.

In a semiconductor device using a process technology with 65 nm, 45 nm or less, the high concentration impurity regions 108 and 118 are often formed under the condition where the concentration becomes maximum at depth of several nm. When majority portions of the high concentration impurity regions 108 and 118 are consumed due to the silicon oxide films 109 and 119, the thickness of the high concentration impurity regions 108 and 118 is reduced and sheet resistance is increased, respectively. As a result, a problem where drive capability and operation speed of the transistor are decreased occurs. Further, as shown in FIG. 10B, the thickness of the silicon oxide film 109 growing in the high concentration impurity regions 108 of the N-channel transistor and the thickness of the silicon oxide films 119 growing in the high concentration impurity regions 118 of the P-channel transistor are different. Therefore, the increase rate of the sheet resistance becomes different and the characteristic balance in the characteristics of both transistors also becomes disrupted.

The increase in the sheet resistance of such impurity regions is not limited to the high concentration impurity regions 108 and 118, but it is needless to say, this occurs in the ion implantation to form the extension regions 107 and 117. Since the extension regions 107 and 117 are formed to be shallower than the high concentration impurity regions 108 and 118, the increase in the sheet resistance caused by the O₂ ashing treatment becomes further greater.

In order to control the growth of the silicon oxide film that causes such reduction in the transistor performance, the adoption of a technique to remove the resist pattern without using the O₂ ashing treatment, is disclosed in Patent Citations 1 and 2.

However, in the technique disclosed in Patent Citation 1, in the case that the dose amount of ion implantation exceeds 1×10¹⁴ cm⁻², since the reaction of ozone or water vapor with the hardened layer formed in the surface portion of the resist film by ion implantation is insufficient, many resist residues are generated on the semiconductor substrate. Consequently, the surface of the semiconductor substrate where the resist film is removed cannot be a clean condition. Further, the component of the resist film is not volatilized and removed but it may be carbonized in the temperature zone of water vapor treatment so as to cause the popping to the resist. In this case, it has been pointed out that the carbonized resist film cannot be removed by the O₂ ashing treatment or any chemical treatment thereafter.

Further, since the technique disclosed in Patent Citation 2 requires a treatment time exceeding 60 minutes, the production throughput is notably decreased. In addition, in the mixed atmosphere with ozone gas and water vapor at approximately 95 deg. C., as similar to the technology described in Patent Citation 1, because the reaction of the hardened layer formed in the surface portion of the resist film is insufficient, the hardened layer is not completely removed, and many resist residues are generated on the semiconductor substrate. Therefore, the cleaning level regarding particles cannot be secured.

Thus, in order to remove the resist residues on the semiconductor substrate, even in the case of cleaning with APM, in the method using APM to etch a base substrate with an etching amount of 1 nm or less in an equivalent silicon oxide thickness and to strike up the particles, the cleaning level of the surface of the semiconductor substrate cannot be secured.

In the meantime, in the case of using SPM exceeding 180 deg. C., a resist film having the hardened layer formed by ion implantation with the dose amount exceeding 1×10¹⁴ cm⁻² can be removed. However, with this technique, it is reported that the abrasion of the silicon oxide film forming a portion of the semiconductor device is great and the semiconductor substrate is oxidized. Consequently, because the sheet resistance in the shallow impurity region as shown in FIGS. 10A and 10B is increased, it is difficult to apply this technique.

The present invention has been proposed by taking the conversional circumstances into consideration, and the objective is to provide a production method for a semiconductor device to remove a resist film having a hardened layer after implementation of the ion implantation with a high dose amount for a short time by hardly causing the semiconductor substrate to oxidize and without generating particles.

### Technical Solution

In order to accomplish the objective, the present invention has adopted technical means mentioned below. In other words, in a production method for a semiconductor device relating to the present invention, first, a pattern of a resist film made of organic polymers is formed on a semiconductor substrate. Next, impurity ions with 1×10¹⁴ cm⁻² or greater of dose amount are implanted into the semiconductor substrate using the resist film pattern as a mask. Then, the resist film pattern used as the ion implantation mask is removed sequentially through an oxidization treatment, a swelling treatment and a removal treatment. In the oxidization treatment, a treatment to oxidize a hardened layer formed in a surface portion of the resist film pattern by the ion implantation is implemented. In the swelling treatment, a treatment to swell the organic polymers composing the resist film pattern where the hardened layer has been oxidized using a chemical solution is implemented. In the removal treatment, the swollen resist film pattern is removed using the chemical solution used in the swelling treatment.

With this configuration, the resist pattern used as the ion implantation mask with 1×10¹⁴ cm⁻² or greater of dose amount can be excellently removed without using ashing treatment with oxygen plasma. As a result, a minute transistor can be stably produced with a good yield. In particular, in a semiconductor device equipped with both an N-channel transistor and P-channel transistor, characteristic differences of both transistors caused by oxidization on the semiconductor substrate surface can be extremely small.

In this production method for a semiconductor device, it is preferable to implement the oxidization treatment under a condition where an oxidant for accelerating an oxidization of carbons contained in the hardened layer is supplied to a resist film pattern formation surface of the semiconductor substrate. Thus, the hardening layer can be efficiently oxidized.

As the oxidant, a chemical solution at a predetermined temperature can be used. In this case, in the oxidization treatment, first, a temperature of the semiconductor substrate is increased up to a temperature of the chemical solution being the oxidant to be supplied as an upper limit before a supply of the chemical solution. Then, after the temperature increase, the chemical solution at the predetermined temperature is supplied to the resist film pattern formation surface of the semiconductor substrate. As the chemical solution, for example, a chemical solution containing hydrogen peroxide is usable. In this case, the predetermined temperature is within a range from 70 deg. C. to 80 deg. C.

Further, as the oxidant, gas at a predetermined temperature is also usable. In this case, in the oxidization treatment, first, a temperature of the semiconductor substrate is increased up to a temperature of oxidation gas being the oxidant to be supplied as an upper limit before a supply of the gas. Then, after the temperature increase, the oxidation gas and oxidization auxiliary gas for enhancing an oxidization reaction between the oxidation gas and the hardened layer are supplied at the predetermined temperature onto the resist film pattern formation surface of the semiconductor substrate. For example, gas containing ozone as the oxidization gas is usable, and gas containing water vapor is usable as the oxidization auxiliary gas. In this case, the predetermined temperature is within a range from 80 deg. C. to 120 deg. C.

In addition, in another aspect of the oxidization treatment, first, gas containing oxygen and water vapor at a predetermined temperature is supplied to the resist film pattern formation surface of the semiconductor substrate; concurrently, an excimer lamp light is irradiated onto the resist film pattern formation surface, and ozone is generated in a vicinity of the resist film pattern formation surface. In this case, before a supply of the gas, a temperature of the semiconductor substrate is increased under a condition where the temperature of the semiconductor substrate to be increased during the oxidization is within a temperature range of lower than a temperature where a carbonization of the organic polymers starts. In this case, the predetermined temperature is within a range from 80 deg. C. to 120 deg. C. Further, if the excimer lamp light is ultraviolet light, the hardened layer can be disintegrated due to the light. Further, gas containing ozone may be supplied to the resist film pattern formation surface of the semiconductor substrate along with the gas containing oxygen and water vapor.

Further, in the above-mentioned production method for a semiconductor device, the swelling treatment and the removal treatment can be implemented by supplying the chemical solution whose capability to dissolve the organic polymers is increased in association with a temperature increase to the resist film pattern formation surface of the semiconductor substrate. In this case, the swelling treatment can be implemented by supplying the chemical solution whose temperature is gradually increased from a temperature zone where the organic polymers are not substantially dissolved through another temperature zone where the organic polymers are substantially dissolved. Further, the removal treatment can be implemented by supplying the chemical solution in the temperature zone where the organic polymers are substantially dissolved to the resist film pattern formation surface of the semiconductor substrate. As this chemical solution, for example, a sulfuric acid-hydrogen peroxide mixture (SPM) or a chemical solution where a dissolved ozone solution is mixed into high temperature sulfuric acid (SOM) are usable. In this case, a temperature to start supplying onto the resist film pattern formation surface of the semiconductor substrate can be within a range from 80 deg. C. to 100 deg. C. Further, in the swelling treatment, a final achievement temperature for the temperature increase of the chemical solution can be within a temperature range which is higher than the start temperature of the temperature increase and is 170 deg. C. or less. It is preferable that a time for swelling the organic polymers by the chemical solution is at least 30 seconds.

Furthermore, after the removal treatment, a substrate cleaning for removing residual particles may be implemented.

The above-mentioned production methods for a semiconductor device is particularly preferable in the case that the step of implanting ions, on an occasion of forming an N-channel transistor and a P-channel transistor, is a step of implementing any of an ion implantation for adjusting he threshold voltage of either of the transistors, an ion implantation for forming an extension region of either of the transistors, and an ion implantation for forming source/drain regions in either of transistors.

### ADVANTAGEOUS EFFECTS

According to the present invention, in a production process of a semiconductor device, even in the case that a hardened layer is formed in a surface portion of a resist film pattern used as an ion implantation mask, the resist film pattern can be excellently removed without using O₂ ashing treatment. As a result, a semiconductor device equipped with an impurity region formed by ion implantation with a high dose amount can be stably produced with high production yield.

### BRIEF DESCRIPTION OF THE DRAWINGS

FIGS. 1A to 1E are cross sectional views showing a part of production process for a semiconductor device in one embodiment relating to the present invention.

FIG. 2 is a flowchart showing treatments from the ion implantation to the resist pattern removal implemented in the production process for a semiconductor device in one embodiment relating to the present invention.

FIG. 3 is a schematic cross sectional view showing a structure of a single-wafer treatment apparatus for implementing a hardened layer oxidation treatment in one embodiment relating to the present invention.

FIG. 4 is a schematic cross sectional view showing a structure of a single-wafer treatment apparatus for implementing a hardened layer oxidation treatment in one embodiment relating to the present invention.

FIG. 5 is a schematic cross sectional view showing a structure of a single-wafer treatment apparatus for implementing a hardened layer oxidation treatment in one embodiment relating to the present invention.

FIG. 6 is a graph showing analysis results of a decomposition process of the hardened layer according to temperatures by TDS method.

FIG. 7 is a schematic cross sectional view showing a structure of a single-wafer treatment apparatus for implementing a resist film swelling treatment in one embodiment relating to the present invention.

FIG. 8 is a graph showing a temporal change of SPM temperature supplied to a wafer in a resist film swelling treatment and a resist removal treatment in one embodiment relating to the present invention.

FIG. 9 is a flowchart showing treatments from the ion implantation to the resist pattern removal in a conventional production process for a semiconductor device including O₂ ashing treatment.

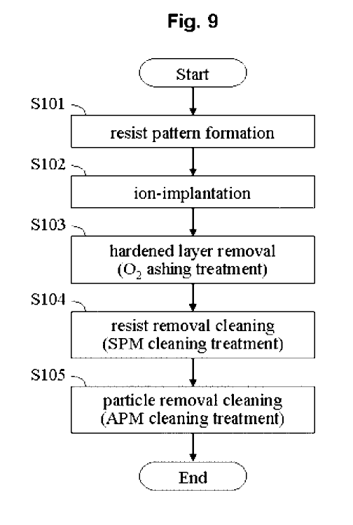

FIGS. 10A and 10B are cross sectional views for explaining an influence of a conventional O₂ ashing treatment on a semiconductor device.

### EXPLANATION OF REFERENCE

1 semiconductor substrate
2 resist film
3 ion species
4 hardened layer
5 impurity region
7 hardened alteration layer
8 alteration layer
11 chuck
13 chemical solution discharge nozzle
14 chemical solution
48 ozone discharge nozzle
49 water vapor discharge nozzle
60 chuck
66 excimer lamp unit
80 infrared lamp
W wafer

### BEST MODE FOR CARRYING OUT THE INVENTION

The present invention sequentially implements, on the occasion of removing a resist film used as an ion implantation mask, a treatment to oxidize a hardened layer formed in a surface portion of the resist film, a treatment to swell the resist film and a treatment to remove the resist film. Hereafter, one embodiment of the present invention will be explained with reference to drawings in detail.

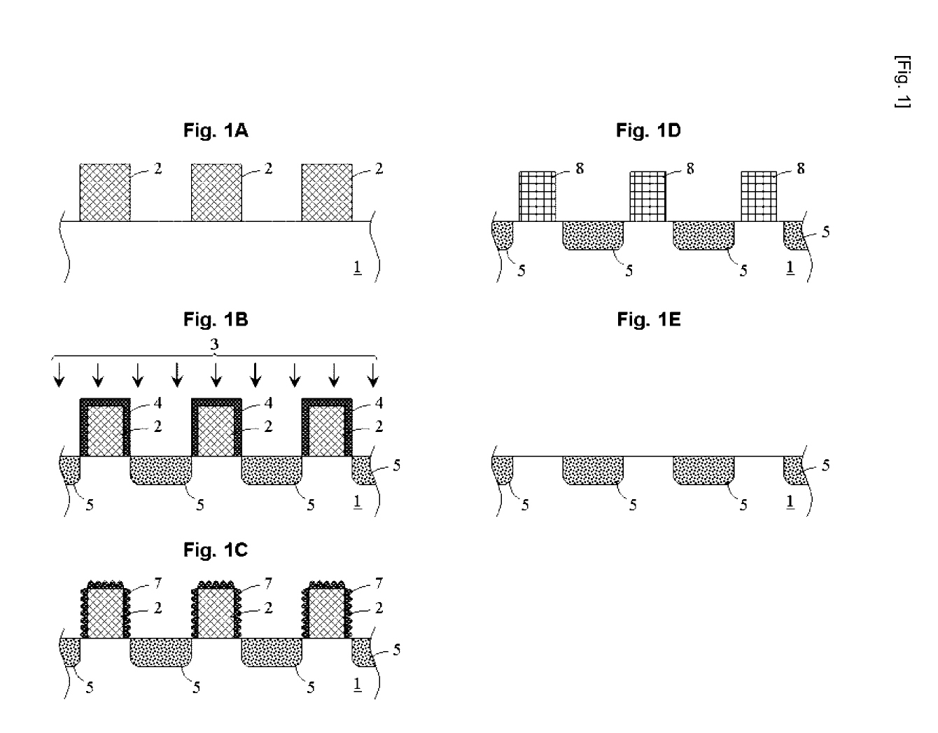

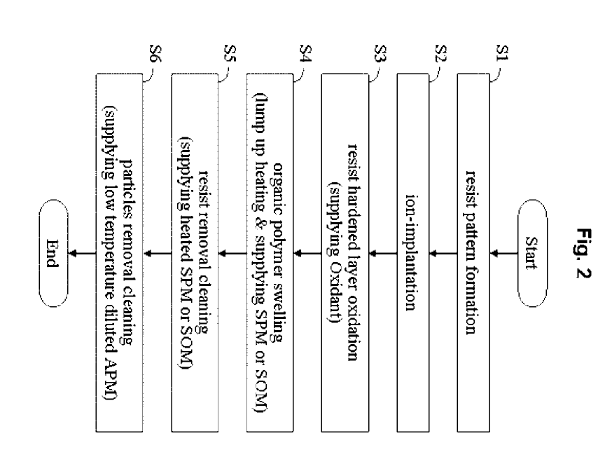

FIGS. 1A to 1E are cross sectional views showing a part of production process for a semiconductor device in one embodiment relating to the present invention. Further, FIG. 2 is a flowchart showing treatments from an ion implantation to a resist film removal implemented in the production process for a semiconductor device in one embodiment relating to the present invention. First, an outline of the treatments implemented in the production method for a semiconductor device relating to the present invention with reference to FIGS. 1A to 1E and FIG. 2, and then, each treatment is described more specifically.

In the case of forming an impurity region in a semiconductor substrate by ion implantation, as shown in FIG. 1A, first, in order to divide a region for implanting impurity ions and a non-implantation region, a pattern made from a resist film 2 for covering a non-implantation region is formed on a semiconductor substrate (silicon substrate) 1 (FIG. 2, step S1). In the example shown in FIG. 1A, the surface of the semiconductor substrate 1 is exposed; however, a film constituting a portion of the semiconductor element may cover other not-shown regions. Further, the resist film 2 is, for example, a chemically-amplified resist film or a novolac resist film used in i-line photolithography, and it is made from various organic polymers including a photosensitive material.

Next, as shown in FIG. 1B, predetermined ion species 3 are ion-implanted into the semiconductor substrate 1 with 1×10¹² cm⁻² or more of dose amount, particularly preferably, 1×10¹⁴ cm⁻² or more of dose amount (FIG. 2, step S2). This causes the formation of an impurity region 5 in the semiconductor substrate 1. This ion implantation includes ion implantation for forming a well layer in the semiconductor substrate 1, ion implantation for adjusting a threshold voltage (Vt) of a MOS transistor, ion implantation for forming an extension region, ion implantation for forming a pocket region adjacent to a source region or a drain region, and ion implantation for forming a source region and a drain region.

In the process of the ion implantation, bonds of molecular in the organic polymers comprising a surface portion of the resist film 2 are broken due to a bombardment by energy of the ion species 3. Further, hydrogen atoms and oxygen atoms in a portion of the organic polymers comprising the surface portion of the resist film 2 are released to the outside of the resist film 2. As a result, carbon atoms exist excessively on the surface portion of the resist film 2. These carbon atoms are bound to each other and form a hardened layer 4 in the surface portion of the resist film 2 as shown in FIG. 1B. Furthermore, it has become clear according to the surface analysis, such as Auger electron spectroscopy (AES), that the hardened layer 4 becomes a layer where the carbon density is increased by releasing oxygen atoms and hydrogen atoms from the organic polymers.

When the ion implantation is completed, the resist film 2 used as the ion implantation mask is removed as mentioned below. In this embodiment, first, an oxidation treatment of the hardened layer 4 formed in the surface portion of the resist film 2 is conducted (FIG. 2, step S3). Herein, the hardened layer 4 is oxidized by supplying an oxidant, such as a chemical solution that can accelerate the oxidation of the hardened layer 4 or gas causing only a surface reaction for oxidizing carbons comprising the hardened layer 4. This oxidation treatment of the hardened layer 4 is aimed at breaking the chemical bonds of many carbons in the hardened layer 4 where carbons excessively exist. This oxidation treatment enables swelling of the resist film in a swelling treatment described below. In this oxidation process using the oxidant, the exposed surface of the semiconductor substrate 1 is slightly oxidized, as well. However, since this is the oxidation due to a reaction with the oxidant, such as a chemical solution or gas only for surface reaction, the notable oxidation due to the reaction in the O₂ ashing treatment with high incident energy accelerating the oxidation will never occur. Furthermore, the oxidation treatment to the hardened layer 4 using the oxidant may be a treatment to completely decompose the hardened layer 4 due to the sufficient the oxidation reaction; however, it can be a treatment to alter the chemical bonds of the hardened layer 4 to be sufficiently weak. The application of this oxidation treatment causes the alteration of the hardened layer 4 and it becomes a hardened alteration layer 7 as shown in FIG. 1C.

When the alteration to the hardened alteration layer 7 due to the oxidation treatment is completed, the organic polymers comprising the resist film 2 are swollen using the heated SPM (FIG. 2, step S4). The swelling treatment is aimed at further weakening the chemical bonds of the hardened alteration layer 7 and breaking the chemical bonds of the organic polymers themselves, and transiting the organic polymers to a condition where they can be easily dissolved. Since the swelling treatment is a treatment with a chemical solution for the purpose of chemically breaking the bonds of organic substances, a sufficient reaction time required for weakening and breaking the bonds of the organic polymers is secured. This treatment, for example, can be realized by prolonging a temperature increase time for heating a SPM to a predetermined temperature as described below. The hardened alteration layer 7 is removed from the surface of the resist film by the swelling treatment; concurrently, as shown in FIG. 1D, only an alteration layer 8 where the resist film 2 existing in the lower layer of the hardened alteration layer 7 is swollen remains on the semiconductor substrate 1. Furthermore, not only the heated SPM, but SOM (sulfuric acid-ozone mixture) where a dissolved ozone solution is mixed into high temperature sulfuric acid can be used for the swelling treatment.

Next, the organic polymers comprising the alteration layer 8 are completely dissolved using SPM whose temperature is sufficiently increased (FIG. 2, step S5). Thus, as shown in FIG. 1E, the semiconductor substrate 1 having a clean surface without any resist residue can be obtained. Furthermore, if necessary, the semiconductor substrate 1 may be cleaned using low temperature diluted APM for removing particles remaining on the semiconductor substrate 1 and restraining the re-adhesion (FIG. 2, step S6).

Subsequently, each process included in the above-described resist film removal treatment will be specifically described. First, the hardened layer oxidation process will be described. Herein, as an example of the hardened layer oxidation process, four aspects are explained.

(First Hardened Layer Oxidation Treatment)

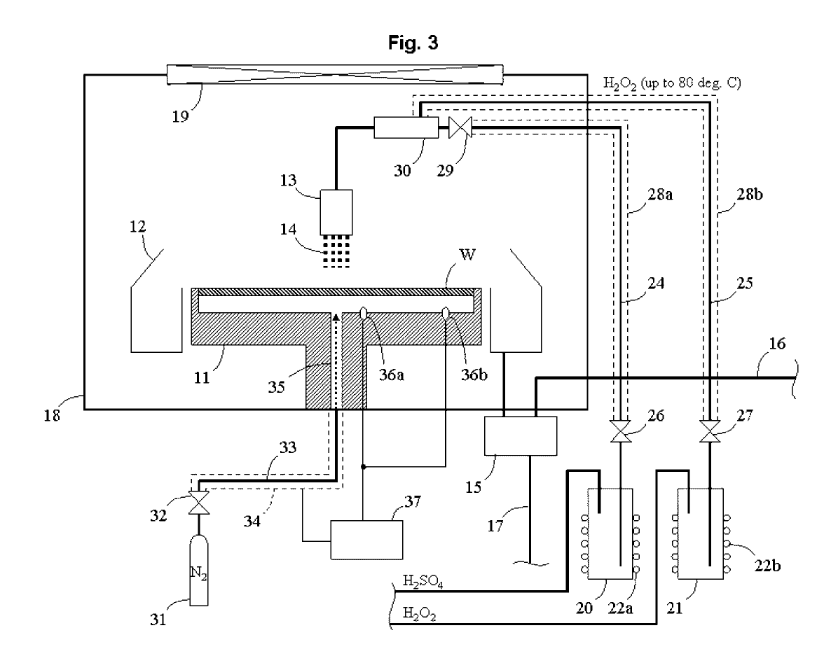

As described above, the hardened layer oxidation treatment is a treatment where the chemical bonds of the hardened layer 4 including excess carbons are broken and the hardened layer 4 is altered to the hardened layer oxidation treatment 7. In a first hardened layer oxidation treatment, while the semiconductor substrate 1 is heated, a hydrogen peroxide solution at 70 deg. C. as the oxidant is supplied to the resist film formation surface of the semiconductor substrate 1. The treatment can be implemented using, for example, a single-wafer treatment apparatus shown in FIG. 3.

FIG. 3 is a schematic cross sectional view showing a structure of the single-wafer treatment apparatus where the hardened layer oxidation treatment is implemented. As shown in FIG. 3, the single-wafer treatment apparatus is equipped with a disc-shaped chuck 11 for securing a semiconductor substrate (wafer) W. The chuck 11 is supported to be rotatable in the horizontal plane by a rotary shaft which is rotated by a not-shown drive unit, such as an electric motor and the like, and linked with the bottom surface thereof.

A chemical solution discharge nozzle 13 for discharging a chemical solution 14 is arranged at the upper side of the chuck 11. The chemical solution discharge nozzle 13 is arranged in a state where a discharge port faces a rotational center of the wafer W mounted on the chuck 11, and supplies the chemical solution 14 to the rotating wafer W. The chemical solution 14 discharged to the rotating wafer W from the chemical solution discharge nozzle 13 spreads toward the outer circumference on the surface of the wafer W. Then, an unreacted chemical solution and the chemical solution reacted with the resist film on the wafer W splash outward from an outer edge of the wafer W. Furthermore, the chemical solution discharge nozzle 13 may be constructed to be oscillatable in parallel to the horizontal plane.

A chemical solution collecting cup 12 placed around the chuck 11 collects the chemical solution 14 splashed from the outer edge of the wafer W. A steam-liquid separating box 15 for separating a waste solution and the chemical solution steam of the chemical solution 14 is connected to the chemical solution collecting cup 12, and the separated waste solution and chemical solution steam are discharged to the outside of the apparatus via a waste solution line 17 and a discharge line 16, respectively. The chemical solution collecting cup 12 is configured to be movable up and down with regard to the chuck 11. In other words, on an occasion of delivering the wafer W to the chuck 11, the chemical solution collecting cup 12 moves down from the position shown in FIG. 3, and on the occasion of supplying the chemical solution 14 to the wafer W mounted on the chuck 11, the chemical solution collecting cup 12 moves up to the position shown in FIG. 3 and the circumference of the wafer W is covered.

Further, the chuck 11, the chemical solution collecting cup 12 and the chemical solution discharge nozzle 13 are arranged within a box-state chamber 18. The configuration enables the discharge of an atmosphere from the chemical solution collecting cup 12 to the outside of the apparatus via the discharge line 16; concurrently, an air draft becomes turbulent in the vicinity of the wafer W, and diffusion of the atmosphere to the outside of the apparatus can be prevented. Further, in the single-wafer treatment apparatus, a high efficiency particulate air filter (HEPA filter) 19 is arranged at a ceiling of the chamber 18 for controlling the air draft above the wafer W, and a smoother air draft control is realized.

The chemical solution discharge nozzle 13 is connected to a tank 21 for storing a hydrogen peroxide solution, which is the chemical solution 14, via a pipe 25. A heater 22b is arranged around the tank 21, and the hydrogen peroxide solution within the tank 21 is maintained at a predetermined temperature. Further, hydrogen peroxide solution is being supplied to the tank 21 from the outside. When a valve 27 inserted in the pipe 25 is released, the hydrogen peroxide solution at the predetermined temperature is force-fed to the chemical solution discharge nozzle 13 via the pipe 25 and a mixing box 30. Furthermore, in order not to cause the decrease in the temperature of the hydrogen peroxide solution in the course of passing the pipe 25, a tape heater 28b is arranged around the pipe 25, and the pipe 25 is maintained at the predetermined temperature.

Furthermore, the single-wafer treatment apparatus shown in FIG. 3 is configured to enable a supply of sulfuric acid to the chemical solution discharge nozzle 13 so as to enable the realization of the swelling treatment for the organic polymers using the heated SPM and the resist removal treatment for dissolving the resist, as detailed later, in succession with the hardened layer oxidation treatment. In other words, the mixing box 30 intervened between the chemical solution discharge nozzle 13 and the valve 27 is connected to a tank 20 for storing sulfuric acid via a pipe 24. As similar to the tank 21, a heater 22a is arranged around the tank 20, and the sulfuric acid within the tank 20 is maintained at a predetermined temperature. Further, sulfuric acid is being supplied to the tank 20 from the outside. When valves 26 and 29 inserted in the pipe 24 are released, the sulfuric acid at the predetermined temperature is force-fed to the mixing box 30 via the pipe 24. The mixing box 30 uniformly blends in the hydrogen peroxide solution supplied via the pipe 25 and the sulfuric acid supplied via the pipe 24, and supplies the mixture to the chemical solution discharge nozzle 13 as SPM. Further, in order not to cause the decrease in the temperature of the sulfuric acid in the course of passing the pipe 24, a tape heater 28a is also arranged around the pipe 24. In the case of supplying SPM to the chemical solution discharge nozzle 13, the tape heaters 28a, 28b around the pipes 24 and 25 and the heaters 22a, 22b for the tank 20 and 21 are set at the same temperature. Further, it is preferable that the tape heaters 28a, 28b for the pipes 24 and 25 and the heaters 22a, 22b for the tanks 20 and 21 enable independent temperature setting, respectively.

Further, the single-wafer treatment apparatus is equipped with a means for controlling a temperature of the wafer W mounted on the chuck 11 for adjusting the entire wafer W during the treatment to be at desired uniform temperature. In other words, nitrogen gas at a predetermined temperature is supplied to the rear surface of the wafer W via a passage 35 placed in the center at the rear side of the wafer W mounted on the chuck 11. This nitrogen gas is introduced from a cylinder 31 to the passage 35 via a pipe 33 controlled at the predetermined temperature by a tape heater 34. A temperature sensor for measuring the rear surface temperature of the wafer W mounted on the chuck 11 is placed on the surface of the chuck 11. In FIG. 3, thermocouples 36a and 36b are arranged in the center and at the outer edge of the chuck 11, and it is configured to adjust the temperature of the nitrogen gas so as to adjust the temperature of the rear surface of the wafer W to be the same as the treatment temperature for the surface of the wafer W based upon the measured temperature at the thermocouples 36a and 36b. The temperature control is realized by adjusting the output of the tape heater 34 by the temperature controller 37.

In the single-wafer treatment apparatus having the above-mentioned configuration, the hardened layer oxidation treatment is implemented as mentioned below. First, before the start of the hardened layer oxidation treatment, in the tank 21, a temperature of the hydrogen peroxide solution, which is an oxidant, is increased. Further, a temperature of the pipe 25 is increased by the tape heater 28b to a temperature according to the temperature of the hydrogen peroxide solution. The temperature of the hydrogen peroxide solution at this time is set to the temperature, which is maintainable at the temperature where the oxidation capability is secured at maximum; simultaneously, the hydrogen peroxide solution is not decomposed as much as possible. For example, the temperature of the hydrogen peroxide solution within the tank 21 is maintained at 70 deg. C. by the heater 22b. Furthermore, it is preferable that the temperature of the hydrogen peroxide solution within the tank 21 is 80 deg. C. or less. This is because hydrogen peroxide is decomposed and the oxidation capability is reduced if the temperature exceeds 80 deg. C.

In the case that the temperature of the hydrogen peroxide solution is maintained at 70 deg. C., the temperature of the nitrogen gas to be discharged onto the rear surface of the wafer W is also set to 70 deg. C., which is the same level as the hydrogen peroxide solution. Thus, when the chemical solution (hydrogen peroxide solution) 14 is discharged from the chemical solution discharge nozzle 13, the decrease in the temperature of the hydrogen peroxide solution on the surface of the wafer W can be prevented. Furthermore, even if the temperature of the nitrogen gas is at approximately 50 deg. C., the temperature of the surface of the wafer W promptly reaches 70 deg. C. in a short time (within 5 seconds) by the hydrogen peroxide solution at 70 deg. C. discharged from the chemical solution discharge nozzle 13. In other words, even in the case that the temperature of the nitrogen gas is lower than the temperature of the chemical solution 14 supplied from the chemical solution discharge nozzle 13, the decrease in the temperature of the hydrogen peroxide solution on the surface of the wafer W can be restrained by increasing the temperature at higher than room temperature. Therefore, for the temperature increase of the wafer W, the temperature of the hydrogen peroxide solution to be supplied should be an upper limit.

For example, the supply of the nitrogen gas onto the rear surface of the wafer W starts 15 seconds prior to a start of discharging the hydrogen peroxide solution onto the surface of the wafer W. Then, while the wafer W is rotated at a predetermined number of revolutions, the supply of the hydrogen peroxide solution at 70 deg. C. to the wafer W from the chemical solution discharge nozzle 13 results in the performance of the hardened layer oxidation treatment. The time to supply the hydrogen peroxide solution at 70 deg. C. to the wafer W is, for example, for approximately 30 seconds. With this treatment, the hardened layer 4 can be altered to the hardened layer alteration layer 7.

(Second Hardened Layer Oxidation Treatment)

In the first hardened layer oxidation treatment, the oxidation treatment was realized by supplying a chemical solution made of a hydrogen peroxide solution to the wafer W. However, the hardened layer oxidation treatment can be realized by supplying not limited to the chemical solution but gas. Then, in this aspect, oxidation gas and oxidation auxiliary gas for enhancing the oxidation reaction between the oxidation gas and the hardened layer are supplied to a wafer formed with the resist film 2 having the hardened layer 4. Here, the configuration to implement the oxidation treatment by supplying ozone (O₃) gas at 80 deg. C. to 120 deg. C. and gas containing water vapor at 80 deg. C. to 120 deg. C. is described.

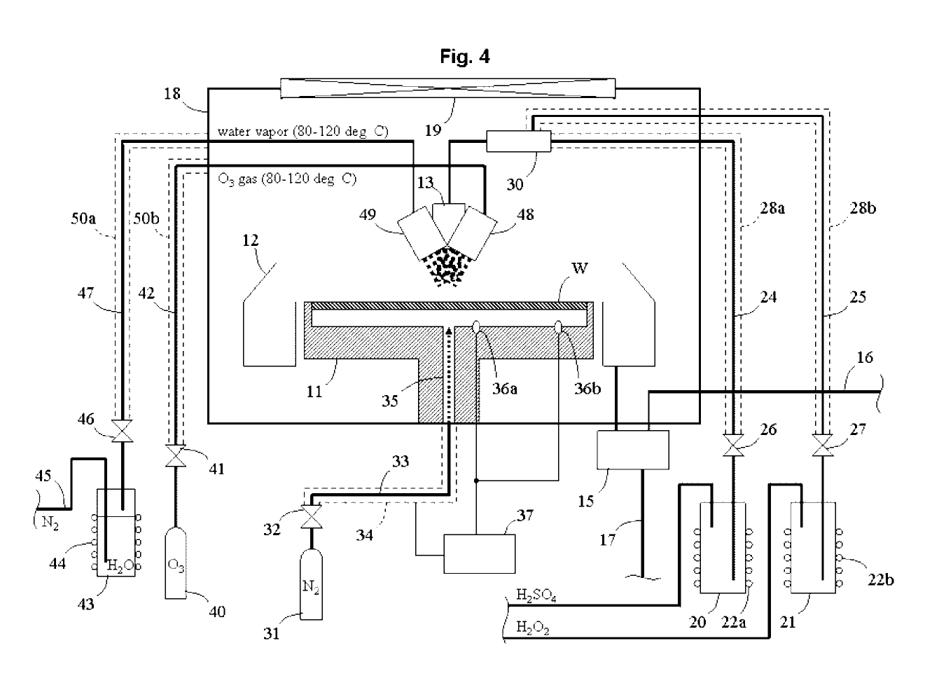

FIG. 4 is a schematic cross sectional view showing a structure of a single-wafer treatment apparatus implementing the hardened layer oxidation treatment in this aspect. In FIG. 4, components having the same function as those in the single-wafer treatment apparatus explained in FIG. 3 are referred to by the same reference numbers and detail description will be omitted herein.

This single-wafer treatment apparatus is a configuration to supply O₃ gas and gas containing water vapor to the wafer W in addition to the configuration to supply a hydrogen peroxide solution and sulfuric acid as similar to the apparatus shown in FIG. 3.

Namely, an O₃ discharge nozzle 48 for discharging O₃ gas and a water vapor discharge nozzle 49 for discharging gas containing water vapor are arranged above the chuck 11, in addition to the chemical solution discharge nozzle 13. The O₃ discharge nozzle 48 and the water vapor discharge nozzle 49 are arranged so as to discharge O₃ gas and gas containing water vapor onto the same section on the wafer W, respectively. In this configuration, the temperature increased O₃ gas and the temperature increased gas containing water vapor are discharged from separate nozzles, and both are mixed on the surface of the wafer W. With this design, the O₃ gas and the gas containing water vapor can be interacted on the surface of the wafer W. Furthermore, the O₃ discharge nozzle 48 and the water vapor discharge nozzle 49 are configured to be oscillatable in parallel to the horizontal plane, and the O₃ gas and the gas containing water vapor can be supplied to the entire surface of the wafer W mounted on the chuck 11

The O₃ discharge nozzle 48 is connected to a cylinder 40 for storing the O₃ gas via a pipe 42. When a valve 41 inserted in the pipe 42 is released, the O₃ gas at a predetermined temperature is supplied to the O₃ discharge nozzle 48 via the pipe 42. Furthermore, a tape heater 50b for increasing a temperature of the O₃ gas to be supplied at the predetermined temperature and maintaining the O₃ gas temperature at the predetermined temperature is arranged around the pipe 42 between the cylinder 40 and the chamber 18.

Further, the water vapor discharge nozzle 49 is connected to a tank 43 for storing purified water (deionized water) via a pipe 47. A heater 44 is arranged around the tank 43, and purified water within the tank 43 is maintained at approximately 100 deg. C. of temperature. Nitrogen gas is supplied to the tank 43 via a pipe 45, and bubbling of the nitrogen gas in purified water at a predetermined temperature causes a generation of gas containing water vapor within the tank 43. When a valve 46 inserted in the pipe 47 is released, the gas containing water vapor at the predetermined temperature is force-fed to the water vapor discharge nozzle 49 via the pipe 47. Furthermore, in order to avoid the temperature of the gas containing water vapor from decreasing and causing dew condensation in the course of passing through the pipe 47, a tape heater 50a is arranged around the pipe 47, and the pipe 47 is maintained at the predetermined temperature.

In the single-wafer treatment apparatus having the above-mentioned configuration, the hardened layer oxidation treatment is implemented as mentioned below. First, before starting the hardened layer oxidation treatment, the pipe 42 and the pipe 47 are heated to a temperature according to a temperature of the O₃ gas and the gas containing water vapor to be supplied to the wafer W. Here, the temperature of the O₃ gas and the gas containing water vapor to be supplied to the wafer W is set in a range from 80 deg. C. to 120 deg. C. At this time, a humidity of the gas containing water vapor is 80% or higher. Furthermore, in order to avoid the O₃ gas from unnecessarily decomposing at high temperature, it is desirable that the upper limit of the O₃ gas temperature is 120 deg. C.

Further, nitrogen gas is discharged onto the rear surface of the wafer W as similar to the first hardened layer oxidation treatment, and the wafer is preliminarily heated. The temperature of nitrogen gas is set to the temperature, which is the same level as that of the O₃ gas and the gas containing water vapor. With this setting, when the O₃ gas and the gas containing water vapor are discharged from the O₃ discharge nozzle 48 and the water vapor discharge nozzle 49, respectively, the decrease in the temperature of the O₃ gas and the gas containing water vapor on the surface of the wafer W can be prevented. Furthermore, even if the temperature of the nitrogen gas is lower than the temperature of the O₃ gas and the gas containing water vapor (for example, when the gas temperature is 120 deg. C., the nitrogen gas is 80 deg. C.), the temperature of the surface of the wafer W promptly reaches that of the O₃ gas and the gas containing water vapor in a short time (within 5 seconds) by the O₃ gas and the gas containing water vapor discharged from the O₃ discharge nozzle 48 and the water vapor discharge nozzle 49. In the hardened layer oxidation treatment implemented with this single-wafer treatment apparatus, as long as the temperature of the wafer W is at least approximately 50 deg. C. to 80 deg. C., it is sufficient to enhance the oxidation reaction of the hardened layer 4 at the portion where the O₃ gas and the gas containing water vapor are supplied. Therefore, an upper limit of the temperature of the nitrogen gas to be supplied to the passage 35 should be the temperature of the gas to be supplied, and for example, it can be set within a range from 70 deg. C. to 120 deg. C.

For example, the supply of the nitrogen gas onto the rear surface of the wafer W starts 15 seconds prior to a start of supplying the O₃ gas and the gas containing water vapor. Then, the supply of the O₃ gas within a range from 80 deg. C. to 120 deg. C. and the gas containing water vapor at the same temperature zone to the same position on the wafer W from the O₃ discharge nozzle 48 and the water vapor discharge nozzle 49 results in the implementation of the hardened layer oxidation treatment. The O₃ gas and the gas containing water vapor are supplied to the wafer W by uniformly scanning (oscillating) the O₃ discharge nozzle 48 and the water vapor discharge nozzle 49 for approximately 20 seconds throughout the entire surface of the wafer W. With this treatment, the hardened layer 4 can be efficiently oxidized, and it can be altered to the hardened alteration layer 7.

In this hardened layer oxidation treatment, the reason why the O₃ gas and the gas containing water vapor are supplied to the same position is because it is necessary that the humidity is 80% or greater, more preferably approximately 100% in order to accelerate the oxidation of the hardened layer 4 in the portion where the O₃ gas and the gas containing water vapor are mixed. The inventors of the present application examined the method to oxidize the hardened layer 4 with a single body of O₃ gas; however, as similar to the method in Japanese Patent Application Laid-Open No. 2006-93473, the hardened layer 4 could not be excellently removed. It appears that this is caused by not accelerating the oxidation of carbons in the hardened layer 4 where excess carbons exist with the single body of O₃ gas. In other words, it appears that an ambient humid atmosphere, containing the humidity 100%, at high temperature contributes to the acceleration of the oxidation reaction in the hardened layer by the O₃ gas. Consequently, in this hardened layer oxidation treatment, the configuration to supply the gas containing water vapor within a range from 80 deg. C. to 120 deg. C. is supplied together to the position supplied the O₃ gas is adopted. Furthermore, if the temperature of the pipe 47 is adjusted at 120 deg. C. by the tape heater 50a, the humidity of the gas containing water vapor becomes substantially 100%.

Furthermore, in the case of the single-wafer treatment apparatus shown in FIG. 4, air within a clean room where temperature and humidity are controlled is inducted inside the chamber 18 via the HEPA filter 19. Further, the discharge of the chamber 18 is not only by the chemical solution collecting cup 12 but also by a not-shown discharging unit arranged in the vicinity of the chuck 11 for the purpose of diffusion prevention of the chemical solution atmosphere. Consequently, the humidity in the chamber 18 becomes within a range from 30% to 40%. Therefore, even if the gas containing water vapor is discharged from the water vapor discharge nozzle 49, as the location is away from the discharge position, the humidity (or amount of water vapor) even on the surface of the wafer W is drastically decreased. Consequently, it is particularly preferable that the humidity at the position supplied the O₃ gas is 100%.

Further, in this hardened layer oxidation treatment, since there is concern that dew condensation may occur on the wafer W due to the supplied gas containing water vapor, it is preferable to discharge each gas onto the wafer W while the wafer W is slowly rotated at 100 rpm or less of the number of revolutions during the oxidation treatment. With this operation, even if the dew condensation occurs to the wafer W, the dew condensation water is discharged to the outside of the wafer W; concurrently, a water film formed on the surface of the wafer W can be thinner. In this case, the O₃ discharge nozzle 48 and the water vapor discharge nozzle 49 are oscillated along the diameter of the wafer W.

(Third Hardened Layer Oxidation Treatment)

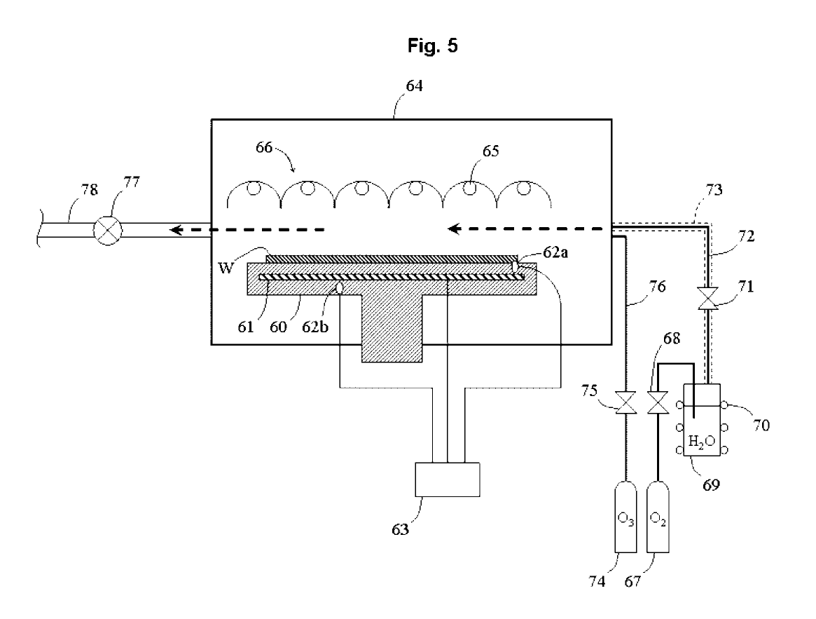

In a third hardened layer oxidation treatment, the heated semiconductor substrate 1 is mounted in O₂ atmosphere containing water vapor within a range from 80 deg. C. to 120 deg. C., and an excimer light is irradiated toward the resist film formation surface in the semiconductor substrate 1 so that ozone is generated. This treatment can be implemented, for example, by using a single-wafer treatment apparatus shown in FIG. 5.

FIG. 5 is a schematic cross sectional view showing a structure of a single-wafer treatment apparatus for implementing this hardened layer oxidation treatment. As shown in FIG. 5, the single-wafer treatment apparatus is equipped with a chuck 60 mounting the wafer W within a closed chamber 64. The chuck 60 secure the wafer W mounted thereon by vacuum suction and the like. A heater 61 comprising a ceramic heater and the like is buried into the chuck 60, and the wafer W mounted on the chuck 60 is maintained at a predetermined temperature. A thermocouple 62a for measuring the temperature of the rear surface of the wafer W is placed in a surface portion of the chuck 60. Further, a thermocouple 62b for measuring the temperature of the chuck 60 is placed in the vicinity of the heater 61. The thermocouples 62a and 62b are connected to a temperature controller 63, respectively, and the temperature controller 63 adjusts the output of the heater 61 to be a condition where the temperature of the wafer W becomes a predetermined temperature based upon the temperatures measured by the thermocouples 62a and 62b and a set temperature. Furthermore, a gap between an excimer lamp unit 66 and the wafer W is set to be approximately 10 mm.

The excimer lamp unit 66 where a plurality of excimer lamps 65 for emitting ultraviolet light having a wavelength within a range of 100 nm to 400 nm (172 nm herein) is arranged is allocated. Each excimer lamp 65 is arranged to face the light irradiation direction against the treatment surface of the wafer W, and each excimer lamp 65 is arranged in a state where the inplane uniformity of the temperature of the wafer W caused by the light irradiation of each excimer lamp 65 is maintained.

In order to supply O₂ gas containing water vapor, a cylinder 67 for storing O₂ gas and a tank 69 for storing purified water (deionized water) are connected to the chamber 64. A heater 70 is arranged around the tank 69, and the purified water within the tank 69 is maintained at the temperature of approximately 100 deg. C. It is configured such that the O₂ gas is introduced into the tank 69 via a pipe with a valve 68, and when the valve 68 is released and the O₂ gas is bubbled in the heated purified water, the O₂ gas containing water vapor is generated within the tank 69. When a valve 71 inserted in a pipe 72 connecting the chamber 64 and the tank 69 is released, the O₂ gas containing water vapor at a predetermined temperature is force-fed to the chamber 64 via the pipe 72. Furthermore, in order to avoid the temperature of the O₂ gas containing water vapor from decreasing and causing dew condensation within the pipe 72 in the course of passing the pipe 72, a tape heater 73 is arranged around the pipe 72, and the pipe 72 is maintained at the predetermined temperature. Furthermore, an exhaust pipe 78 is connected to the position facing against the connection position of the pipe 72 on the sidewall of the chamber 64. On the occasion of introducing gas into the chamber 64, it is configured such that a valve 77 inserted in the exhaust pipe 78 is released and gas can be smoothly introduced into the chamber 64.

In the single-wafer treatment apparatus having the above-mentioned configuration, the hardened layer oxidation treatment is implemented as mentioned below. First, the temperature controller 63 adjusts the temperature of the chuck 60 to a predetermined temperature within a range of 80 deg. C. to 150 deg. C. (for example, 120 deg. C.) based upon the temperatures measured by the thermocouples 62a and 62b. Next, the wafer W is mounted onto the chuck 60. The temperature of the wafer W mounted on the chuck 60 becomes substantially the same temperature as the chuck 60. Further, at this time, the tape heater 73 is set to the temperature according to the temperature of the O₂ gas (80 deg. C. to 120 deg. C. herein) to be supplied onto the surface of the wafer W. After this, upon releasing the valve 71 inserted in the pipe 72, the O₂ gas containing water vapor generated within the tank 69 is introduced into the chamber 64. As a result of this, inside of the chamber 64 becomes atmosphere with the O₂ gas containing water vapor having the temperature within a range of 80 deg. C. to 120 deg. C. formed in the chamber 64. With this operation, the humidity of the O₂ gas containing water vapor becomes 80% or greater. Further, when the temperature of the gas is set to 120 deg. C. by the tape heater 73, the humidity of the O₂ gas containing water vapor becomes substantially 100%.

In this condition, when the excimer light is irradiated from the excimer lamp unit 66 onto the surface of the wafer W having the resist film where the hardened layer 4 is formed, oxygen in the O₂ gas containing water vapor is excited and ozone is generated from the reaction of the excited oxygen. As a result, the O₃ gas is reacted with the hardened layer 4 in the water vapor atmosphere so that a reaction of oxidizing carbon components in the hardened layer 4 is started. Further, in this hardened layer oxidation treatment, decomposition of carbon bonds caused by directly irradiating the ultraviolet light onto the hardened layer 4 is also activated. Furthermore, the irradiation time of the excimer light is approximately 15 seconds. With this operation, the oxidation treatment of the hardened layer 4 can be conducted.

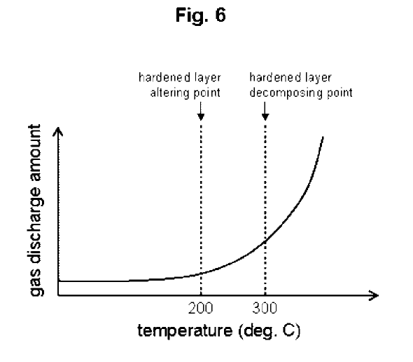

In the above-mentioned hardened layer oxidation treatment, the heating of the wafer W by the heater 61 has an effect to prevent the surface temperature of the wafer W from decreasing in an initial period when the O₂ gas containing water vapor is introduced into the chamber 64. Further, the irradiation of the excimer light causes the generation of O₃ gas; simultaneously, results in the effect to increase the temperature of the wafer W, and the temperature of the wafer W is increased by an amount of from 30 deg. C. to 50 deg. C. compared to an initial temperature of mounting onto the chuck 60. Therefore, the temperature of the wafer W when the excimer light is irradiated and the oxidation treatment is applied reaches 110 deg. C. to 200 deg. C. This temperature is in a temperature zone in which the hardened layer 4 starts to be decomposed only with the temperature. With this operation, the decomposition of the hardened layer 4 in the O₃ gas atmosphere containing water vapor becomes further easier. FIG. 6 is a graph showing results of analyzing a decomposition process according to the temperature of the hardened layer 4 formed by the ion implantation using the thermal desorption spectroscopy (TDS) method. In FIG. 6, the horizontal axis corresponds to the temperature and the vertical axis corresponds to a discharge amount of gas to be discharged to the outside from the resist film. As shown in FIG. 6, when the temperature becomes 200 deg. C. or higher, the gas discharge amount starts increasing. This is because a substance containing a —CH system or a benzene ring starts to be discharged together with a water content, and it is assumed that an alteration of the resist film 2 including the hardened layer 4 at the temperature of approximately 200 deg. C. Further, when the temperature becomes 300 deg. C. or higher, the increase in the gas discharge amount becomes further obvious. Thus, in the temperature region where the gas discharge amount is remarkably increased, it is assumed that a carbonization of the resist film 2 including the hardened layer 4 progresses.

The temperature of the wafer W continues to increase at a constant rate after starting the irradiating of the excimer light. Because of this, so as to have the wafer temperature at the time of completion of excimer light irradiation to complete the oxidation treatment not exceeding 250 deg. C., it is preferable that a heating temperature in the chuck 60 or an irradiation time of the excimer light (15 seconds in this aspect where a final temperature is set to 200 deg. C.) is set. This is because if the final temperature exceeds 250 deg. C., it is not preferable that the carbonization of the organic polymers comprising the resist film 2 starts.

As described above, this hardened layer oxidation treatment is to use a mixed gas of high temperature water vapor and the O₂ gas in association with the excimer light irradiation. Further, in this aspect, it is assumed that the high temperature water vapor enhances the oxidation reaction between the O₃ gas generated by irradiation of the ultraviolet light and the hardened layer 4 so that the oxidation can be efficiently accelerated.

Furthermore, in the single-wafer treatment apparatus shown FIG. 5, the cylinder 74 where O₃ gas is stored is connected to the chamber 64 via a pipe 76. The pipe 76 is connected to the chamber 64 in the vicinity of the connection section between the pipe 72 and the chamber 64. When a valve 75 inserted in the pipe 76 is released, the O₃ gas is supplied from the cylinder 74 into the chamber 64. This O₃ gas is used when the oxidation reaction of the hardened layer 4 does not sufficiently progress only with O₃ generated by irradiating the ultraviolet light from the excimer lamp unit 66 within the chamber 64 in which the O₂ gas atmosphere containing water vapor is formed.

(Fourth Hardened Layer Oxidation Treatment)

Herein, the hardened layer oxidation treatment in association with the introduction of the O₃ gas by the pipe 76 will be described.

First, the temperature controller 63 adjusts the temperature of the chuck 60 to a predetermined temperature within a range of 80 deg. C. to 150 deg. C. (for example, 120 deg. C.) based upon the temperatures measured by the thermocouples 62a and 62b. Next, the wafer W is mounted onto the chuck 60. The temperature of the wafer W mounted on the chuck 60 becomes substantially the same temperature as the chuck 60. Further, at this time, the tape heater 73 is set to the temperature according to the temperature of O₂ gas (herein, 80 deg. C. to 120 deg. C.) to be supplied onto the surface of the wafer W. After this, upon releasing the valve 71 inserted in the pipe 72, the O₂ gas containing water vapor generated within the tank 69 is introduced into the chamber 64. Further, upon releasing the valve 75 inserted in the pipe 76, the O₃ gas is introduced from the cylinder 74 to the chamber 64. With this operation, inside of the chamber 64 becomes atmosphere with the O₂ gas containing water vapor and the O₃ gas. With this operation, the humidity of the gas within the chamber 64 becomes 80% or greater. Further, when the gas temperature is adjusted to 120 deg. C., the gas humidity within the chamber 64 is substantially 100%.

In this condition, when the excimer light is irradiated from the excimer lamp unit 66 onto the surface of the wafer W having the resist film where the hardened layer 4 is formed, O₂ within the chamber 64 is converted into O₃. As a result, the O₃ gas is reacted with the hardened layer 4 in the water vapor atmosphere so that a reaction of oxidizing carbon components in the hardened layer 4 is started. Further, in this hardened layer oxidation treatment, decomposition of carbon bonds caused by directly irradiating the ultraviolet light onto the hardened layer 4 is also activated. Furthermore, the irradiation time of the ultraviolet light is approximately 15 seconds. With this operation, the oxidation treatment of the hardened layer 4 can be conducted.

In the above-mentioned hardened layer oxidation treatment, addition of the O₃ gas enables improvement of the oxidation decomposition effect compared to the third hardened layer oxidation treatment. Therefore, even if the oxidation of the hardened layer 4 is insufficient only with O₂ gas containing water vapor depending upon a dose amount or a resist type, the hardened layer 4 can be efficiently oxidized.

Furthermore, in the third and fourth hardened layer oxidation treatments, the O₂ gas containing a great deal of water vapor is used; however, as a substitute for the O₂ gas, atmosphere not containing a contaminant, such as alkali ion and the like, can be used. Even in the case of using such atmosphere, the generation amount of the ozone due to irradiation of the excimer light becomes the same level.

(Swelling Treatment and Removal Treatment of Resist Film)

Subsequently, a resist film swelling treatment and a resist film removal treatment to be sequentially implemented after the hardened layer oxidation treatment will be described.

The resist film swelling treatment is implemented by supplying a chemical solution whose capability to dissolve organic polymers comprising a resist film is increased in association with the temperature increase, such as SPM, SOM, and the like, onto a wafer where the hardened layer oxidation treatment is completed. In this case, the chemical solution is supplied to the wafer under a condition where the temperature is gradually increased from a temperature zone, where the organic polymers are not substantially dissolved, to another temperature zone, where the organic polymers are substantially dissolved. Then, when the chemical solution reaches a predetermined temperature, the chemical solution is supplied for a certain period of time at the reached temperature. The resist film removal treatment is implemented by the supply of the chemical solution for this certain period of time.

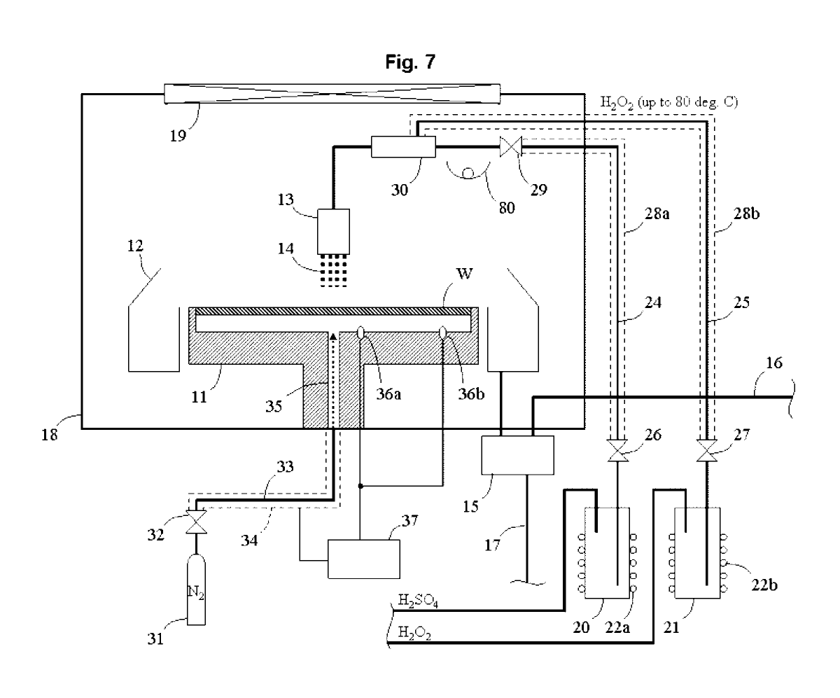

FIG. 7 is a schematic cross sectional view showing a structure of a single-wafer treatment apparatus for implementing the resist film swelling treatment and removal treatment. Since this apparatus has a configuration as similar to the single-wafer treatment apparatus shown in FIG. 3, components having the same function as those in the single-wafer treatment apparatus explained in FIG. 3 are referred to by the same reference numbers and detailed description will be omitted.

The single-wafer treatment apparatus shown in FIG. 7 is different from the apparatus shown in FIG. 3 in the point having an infrared heater 80. The infrared heater 80 is composed with an infrared lamp, and is arranged between the valve 29 of the pipe 24 for supplying sulfuric acid and the mixing box 30 so as to be heatable the pipe 24. The infrared heater 80 heats sulfuric acid passing within the pipe 24 to a predetermined temperature at a predetermined temperature increase speed

In the single-wafer treatment apparatus having the above-mentioned configuration, the swelling treatment and the removal treatment are implemented as mentioned below. First, before starting the swelling treatment, sulfuric acid stored in the tank 20 is maintained within a range of 80 deg. C. to 100 deg. C. by the heater 22a and the tape heater 28a, and sent to the valve 29. When the swelling treatment is started, the valve 29 is released. At this time, while the temperature of sulfuric acid flowing within the pipe 24 is increased, for example, from the initial temperature within a range of 80 deg. C to 100 deg. C. to approximately 160 deg. C. at a constant temperature increase speed by the infrared heater 80 turned on at the time of the start of the swelling treatment, the sulfuric acid is introduced into the mixing box 30. For example, the temperature of the sulfuric acid is gradually increased by taking time for approximately 30 seconds.

In the meantime, when the swelling treatment is started, the valve 27 is released and hydrogen peroxide solution stored in the tank 21 is also supplied to the mixing box 30. Herein, the hydrogen peroxide solution is sent to the mixing box via the pipe 25 while it is heated by the heater 22b and the tape heater 28b at 40 deg. C. The hydrogen peroxide solution is introduced into the mixing box 30 as is, and mixed with the sulfuric acid supplied via the pipe 24 in the mixing box 30. With this operation, SPM is generated.

Since the temperature of the sulfuric acid supplied to the mixing box 30 is increased by the infrared heater 80 at the constant temperature increase speed, the temperature of the chemical solution (SPM) generated in the mixing box 30 and supplied to the chemical solution discharge nozzle 13 shall be increased at the constant temperature increase speed. At last, SPM is temporally stable at approximately 170 deg. C. due to a temperature increase caused by a reaction heat when the sulfuric acid at approximately 160 deg. C. and hydrogen peroxide at 40 deg. C. are mixed and the mixture is discharged from the chemical solution discharge nozzle 13 onto the wafer W. In this aspect, the supply of the SPM at 170 deg. C. onto the wafer W is continued for 20 seconds. With this operation, the resist film 2 on the wafer W can be excellently removed without remaining particles. Furthermore, the supply of the chemical solution to the wafer W is implemented while the chuck 11 is rotated at approximately from 50 rpm to 500 rpm, preferably, at approximately 100 rpm of the number of revolutions.

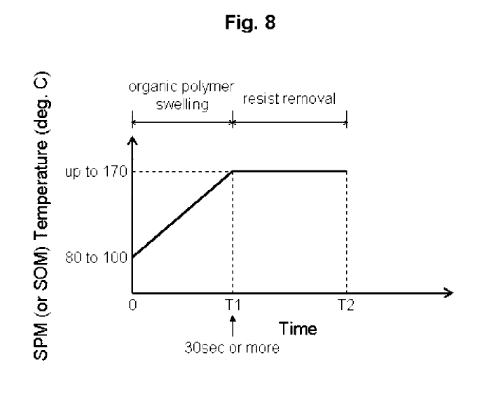

FIG. 8 is a graph showing a temporal change of a SPM temperature to be supplied to the wafer in the swelling treatment and the removal treatment. In FIG. 8, the horizontal axis represents time and the vertical axis represents the SPM temperature. As shown in FIG. 8, the SPM temperature is increased at the constant temperature increase speed from a treatment start time (time “0”) to a time T1. This elevation period is a period of the swelling treatment of the resist film. A period, from the time T1 to a time T2, maintained at a temperature reached during the elevation period continuous from the elevation period is a period for the removal treatment. Thus, the swelling treatment and the removal treatment can be continuously implemented using the same treatment apparatus and the same chemical solution. In order to secure at least 30 seconds as the elevation period, it is preferable that the constant temperature increase speed of the SPM temperature from the time “0” to the time T1 is set at, for example, from 0.1 to 5 deg. C./sec. In this case, the temperature of wafer W is also increased close to with the constant temperature increase speed. In the meantime, if SPM at approximately 160 deg. C. is supplied from the time “0”, since the temperature of the wafer W is increased at a constant temperature increase speed at 10 deg. C./sec or faster, a time sufficient for the swelling treatment can no longer be secured. In addition, when the high temperature SPM is supplied to the wafer W from the time “0”, the hardened alteration layer 7 is drastically carbonized and it becomes difficult to completely remove the resist film 2.

Furthermore, as described above, pre-heating the sulfuric acid within a range of 80 deg. C. to 100 deg. C. enables an improvement of the treatment throughput compared to the case of heating from room temperature. Further, 170 deg. C., which is the highest temperature of SPM in this aspect, is the temperature, which will never grow a thick silicon oxide film that adversely affects a characteristic of the semiconductor device on the surface of the impurity region formed in the semiconductor substrate or will never etch the semiconductor substrate unnecessarily. When the SPM temperature exceeds 180 deg. C., since the possibility to form a thick silicon oxide film or to unnecessarily etch the semiconductor substrate, it is desirable that the SPM temperature to be supplied to the wafer W in the swelling treatment and the removal treatment is 180 deg. C. or less.

Furthermore, in the above-mentioned aspect, SPM where the sulfuric acid whose temperature is gradually increased and the hydrogen peroxide solution at 40 deg. C. are mixed is used for the swelling treatment and the removal treatment; however, as a substitute for the SPM, SOM where 50 ppm of ozone water at 50 deg. C. is added to a sulfuric acid whose temperature is gradually increased can be used. However, from a viewpoint of concentration stability, it is desirable to use the SPM.

Thus, the supply of the chemical solution, such as SPM and the like, to the wafer W while the temperature is gradually increased using the lamp-up heating results in providing the reaction time to weaken and break the chemical bonds of the organic polymers in the hardened alteration layer 7 before the hardened alteration layer 7 is carbonized. Consequently, in a stage where the chemical solution temperature is sufficiently increased (for example, 170 deg. C.), the chemical bonds of the hardened alteration layer 7 is broken, and the hardened alteration layer 7 can be easily dissolved into the chemical solution in the removal treatment after this. Further, the resist film 2 existing in the lower layer of the hardened alteration layer 7 (see FIG. 1C) is altered to the alteration layer 8 in the swelling treatment, and is completely dissolved in the removal treatment. Therefore, the entire resist film 2 can be almost completely removed.

Furthermore, even in the single-wafer treatment apparatus shown in FIG. 7, if the temperature of the pipe 24 is controlled to the predetermined temperature at each section by the tape heater 28a and the infrared heater 80, and the above-described hardened layer oxidation treatment can be implemented. Further, even in the apparatuses shown in FIG. 3 and FIG. 4, the temperature adjustment by the tape heater 28a for heating the pipe 24 results in the realization of the temperature adjustment of sulfuric acid similar to the infrared lamp 80, and enables the use of the swelling treatment and the removal treatment.

Thus, the hardened layer treatment, the swelling treatment and the removal treatment of the present invention are specifically explained. In the case of removing the resist film using these treatments, at least one of the first to fourth hardened layer oxidation treatments, the swelling treatment and the removal treatment should be implemented. Hereafter, examples in the case of implementing the resist film removal by the specific combination will be described.

### Execution Example 1

The first hardened layer oxidation treatment, the resist film swelling treatment and the resist film removal treatment were applied to a resist film where a resist As⁺ for KrF excimer lithography was ion-implanted under conditions of 20 keV of implantation energy and 5×10¹⁵ cm⁻² of implantation dose amount. This enabled excellent removal of the resist film without generating any resist residue. Further, with the As dose amount up to 2×10¹⁵ cm⁻², the treatment time including the hardened layer oxidation treatment with the hydrogen peroxide solution, the resist film swelling treatment and the resist film removal treatment could be realized with 80 seconds or less.

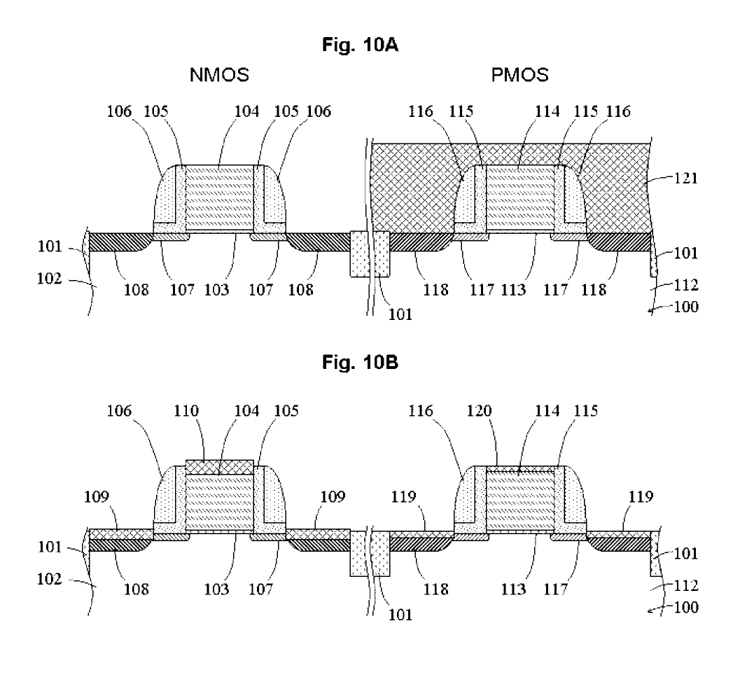

Further, in the case of applying this technique for the removal of a resist film used as the ion implantation mask of the highly-concentrated impurity region as shown in FIGS. 10A and 10B, the oxidized film thickness on the surface of the high-concentration impurity region was restrained at approximately 1 nm. As a result, the resistance increase in the impurity region can be restrained, and an effect where a current value (Ids) between the source and drain indicating a drive capability of the MOS type transistor along with the P-channel transistor and the N-channel transistor increased by 3% or more was obtained compared to the case of conventional resist removal method using the O₂ ashing treatment.

### Execution Example 2

The second hardened layer oxidation treatment, the resist film swelling treatment and the resist film removal treatment were applied to a resist film where a resist As⁺ for KrF excimer lithography was ion-implanted under conditions of 20 keV of implantation energy and 5×10¹⁵ cm⁻² of implantation dose amount. This enabled excellent removal of the resist film without generating any resist residue.

Further, in the case of applying this technique for the removal of the resist film used as the ion implantation mask of the highly-concentrated impurity region as shown in FIGS. 10A and 10B, the oxidized film thickness on the surface of the high-concentration impurity region was restrained at approximately 0.5 nm. As a result, the resistance increase in the impurity region can be restrained, and an effect where Ids indicating the drive capability of the MOS type transistor along with the P-channel transistor and the N-channel transistor increased by approximately 5% was obtained compared to the case of conventional rests removal method using the O₂ ashing treatment.

### Execution Example 3

The third hardened layer oxidation treatment, the resist film swelling treatment and the resist film removal treatment were applied to a resist film where a resist As⁺ for KrF excimer lithography was ion-implanted under conditions of 20 keV of implantation energy and 5×10¹⁵ cm⁻² of implantation dose amount. This enabled excellent removal of the resist film without generating any resist residue.

Further, in the case of applying this technique for the removal of the resist film used as the ion implantation mask of the high-concentration impurity region as shown in FIGS. 10A and 10B, an effect similar to the example 2 could be obtained.

### Execution Example 4

The fourth hardened layer oxidation treatment, the resist film swelling treatment and the resist film removal treatment were applied to a resist film where a resist As⁺ for KrF excimer lithography was ion-implanted under conditions of 20 keV of implantation energy and 5×10¹⁵ cm⁻² of implantation dose amount. This enabled excellent removal of the resist film without generating any resist residue.

Further, in the case of applying this technique for the removal of the resist film used as the ion implantation mask of the high-concentration impurity region as shown in FIGS. 10A and 10B, an effect similar to the example 2 could be obtained.

### Comparative Example 1

For the purpose of comparison with the examples 1 to 4, attempts where conventional resist removal techniques without using the O₂ ashing treatment applied to a resist film where a resist As⁺ for KrF excimer lithography was ion-implanted under conditions of 20 keV of implantation energy and 5×10¹⁵ cm⁻² of implantation dose amount is removed without using the O₂ ashing treatment and effects thereof will be described.

First, a batch type resist removal using SPM to the resist film was applied. The batch type resist removal using SPM is a resist removal method where a plurality of semiconductor substrates where a resist film is formed, respectively, are simultaneously immersed into a chemical solution bath filled with SPM at a predetermined temperature, and the resist films are dissolved.

In the case of using SPM at 140 deg. C., even with the resist film where As whose atomic radius is comparatively greater was implanted, if an immersion time comparatively prolonged and the APM cleaning for removal of particles is combined, the resist films can be removed up to approximately 1×10¹⁵ cm⁻² of dose amount. However, in this technique, approximately 30 minutes of treatment time is required, and if the dose amount becomes 4×10¹⁵ cm⁻² or more, only the resist film 2 in the lower layer of the hardened layer 4 is dissolved and become hollow, and the hardened layer 4 remains, and resist films cannot be removed.

In the case of using SPM around 150 deg. C., popping-shaped residues may be generated to the semiconductor substrate. In addition, in the case of bath method, the concentration of sulfuric acid and the concentration of hydrogen peroxide solution in SPM are substantially stable around 140 deg. C.; however, if the temperature of SPM exceeds 140 deg. C., it becomes difficult to stably maintain the concentration of hydrogen peroxide solution. As another method, after resist film is immersed into water for approximately 168 hours for the purpose of swelling the resist film where ions were implanted, the SPM treatment is conducted, no removal effect is confirmed.

### Comparative Example 2

Further, as another comparative example, a single-wafer resist removal using SPM was applied to a resist film where a resist As⁺ for KrF excimer lithography was ion-implanted under conditions of 20 keV of implantation energy and 5×10¹⁵ cm⁻² of implantation dose amount. The single-wafer resist removal using SPM is a resist removal method where SPM generated by mixing sulfuric acid and hydrogen peroxide immediately before spraying is discharged onto a wafer and the resist film is dissolved.

In this method, the temperature of sulfuric acid and hydrogen peroxide solution is within a range from 85 deg. C. to 110 deg. C.; however, the surface temperature on the wafer surface can be temperature exceeding 150 deg. C. due to the temperature increase caused by the reaction of SPM. However, a resist film where As was ion-implanted with approximately 1×10¹⁵ cm⁻² of implantation dose amount cannot be removed with the single-wafer method even if spraying for a long time, for approximately 2 minutes. Also, if B⁺ whose atomic radius is comparatively small is used, a resist film where up to approximately 1×10¹⁵ cm⁻² of dose amount was ion-implanted is removable; however, another resist film where 4×10¹⁵ cm⁻² of dose amount was implanted cannot be removed.

As described above, according to the present invention, without using the O₂ ashing treatment, even a resist film where a high dose is implanted can be excellently removed without generating residues, which will be a cause of particles, such as a resist residue.

Furthermore, the present invention shall not be limited to the embodiments as described above, but various modifications and applications are possible without departing from the technical concept of the present invention. For example, the configuration where a wafer W is heated from the rear surface in a single-wafer treatment apparatus is not limited to the above-mentioned configuration, but any configuration can be adopted.

### INDUSTRIAL APPLICABILITY

The present invention is useful as a production method for a semiconductor device because a resist film having a hardened layer after a high dose amount of ion implantation is conducted can be excellently removed in a short time without oxidizing the semiconductor substrate.

1. A production method for a semiconductor device, comprising:
a step of forming a pattern of a resist film made of organic polymers on a semiconductor substrate;
a step of implanting ions into the semiconductor substrate with 1×10¹⁴ cm⁻² or greater of dose amount using the resist film pattern as a mask;
a oxidation step of oxidizing a hardened layer formed in a surface portion of the resist film pattern by the ion implantation;
a swelling step of swelling organic polymers comprising the resist film pattern using a chemical solution after the oxidation step; and
a removal step of removing the resist film pattern using the chemical solution after the swelling step.

2. The production method for a semiconductor device according to claim 1, wherein the oxidation step is implemented under a condition where an oxidant for accelerating an oxidation of carbons contained in the hardened layer is supplied to a resist film pattern formation surface of the semiconductor substrate.

3. The production method for a semiconductor device according to claim 2, wherein the oxidant is a chemical solution at a predetermined temperature; and the oxidation step comprises:
a step of increasing a temperature of the semiconductor substrate before a supply of the chemical solution being the oxidant, an upper limit of the temperature of the semiconductor substrate being a temperature of the chemical solution to be supplied as the oxidant; and
a step of supplying the chemical solution being the oxidant to the resist film pattern formation surface of the semiconductor substrate.

4. The production method for a semiconductor device according to claim 3, wherein the chemical solution is a chemical solution containing hydrogen peroxide, and the predetermined temperature is within a range from 70 deg. C. to 80 deg. C.

5. The production method for a semiconductor device according to claim 2, wherein the oxidant is gas at a predetermined temperature; and
the oxidation step comprises:
a step of increasing a temperature of the semiconductor substrate before a supply of oxidation gas being the oxidant, an upper limit of the temperature of the semiconductor substrate being a temperature of the oxidation gas to be supplied as the oxidant; and
a step of supplying the oxidation gas and oxidation auxiliary gas for enhancing an oxidation reaction between the oxidation gas and the hardened layer onto the resist film pattern formation surface of the semiconductor substrate.

6. The production method for a semiconductor device according to claim 5, wherein the oxidation gas is gas containing ozone, and the oxidation auxiliary gas is gas containing water vapor.

7. The production method for a semiconductor device according to claim 2, wherein the oxidation step comprises:
a step of supplying gas containing oxygen and water vapor at a predetermined temperature to the resist film pattern formation surface of the semiconductor substrate, concurrently, generating ozone in a vicinity of the resist film pattern formation surface by irradiating an excimer lamp light to the resist film pattern formation surface; and
a step of increasing a temperature of the semiconductor substrate, before a supply of the gas, under a condition where the temperature of the semiconductor substrate to be increased during the oxidation is within a temperature range of lower than a temperature where a carbonization of the organic polymers starts.

8. The production method for a semiconductor device according to claim 7, wherein the gas containing oxygen and water vapor along with gas containing ozone are supplied to the resist film pattern formation surface of the semiconductor substrate.

9. The production method for a semiconductor device according to claim 7, wherein the excimer lamp light is ultraviolet light.

10. The production method for a semiconductor device according to claim 8, wherein the excimer lamp light is ultraviolet light.

11. The production method for a semiconductor device according to claim 6, wherein the predetermined temperature is within a range from 80 deg. C. to 120 deg. C.

12. The production method for a semiconductor device according to claim 7, wherein the predetermined temperature is within a range from 80 deg. C. to 120 deg. C.

13. The production method for a semiconductor device according to claim 1, wherein the swelling step and the removal step are implemented by supplying the chemical solution whose capability to dissolve the organic polymers is increased in association with a temperature increase to a resist film pattern formation surface of the semiconductor substrate, and the swelling step is implemented by supplying the chemical solution whose temperature is gradually increased from a temperature zone where the organic polymers are not substantially dissolved through another temperature zone where the organic polymers are substantially dissolved.

14. The production method for a semiconductor device according to claim 13, wherein the removal step is implemented by supplying the chemical solution in the temperature zone where the organic polymers are substantially dissolved to the resist film pattern formation surface of the semiconductor substrate.

15. The production method for a semiconductor device according to claim 13, wherein the chemical solution is a sulfuric acid-hydrogen peroxide mixture (SPM) or a chemical solution where a dissolved ozone solution is mixed into high-temperature sulfuric acid (SOM), and a temperature to start supplying onto the resist film pattern formation surface of the semiconductor substrate is within a range from 80 deg. C. to 100 deg. C.

16. The production method for a semiconductor device according to claim 15, wherein a final achievement temperature of the temperature increase is within a temperature range which is higher than the start temperature of the temperature increase and is 170 deg. C. or less.

17. The production method for a semiconductor device according to claim 15, wherein a time for swelling the organic polymers by the chemical solution is at least 30 seconds.

18. The production method for a semiconductor device according to claim 16, wherein a time for swelling the organic polymers by the chemical solution is at least 30 seconds.

19. The production method for a semiconductor device according to claim 1, further comprising a step of removing residual particles after the removal step.

20. The production method for a semiconductor device according to any one of claims 1 to 19, wherein the step of implanting ions, on an occasion of forming an N-channel transistor and a P-channel transistor, is a step of implementing any of an ion implantation for adjusting threshold voltage of either of the transistors, an ion implantation for forming an extension region of either of the transistors, and an ion implantation for forming source/drain regions of either of the transistors.
